(19) United States
(12) Patent Application Publication
(10) Pub. No.: US 2007/0184640 A1
(43) Pub. Date: Aug. 9, 2007

(54) Method for producing solid element plasma and its plasma source

(75) Inventors: Hag-Joo Lee, Seoul (KR); Bong-Ju Lee, Taejeon (KR)

Correspondence Address: HOFFMANN & BARON, LLP, 6900 JERICHO TURNPIKE, SYOSSET, NY, 11791, US

(73) Assignees: KOREA BASIC SCIENCE INSTITUTE, Daejeon (KR); SEM TECHNOLOGY CO., LTD., Seoul (KR)

(21) Appl. No.: 11/597,780

(22) PCT Filed: May 17, 2005
(86) PCT No.: PCT/KR05/01432

§ 371 Date: Nov. 27, 2006

(30) Foreign Application Priority Data
May 28, 2004 (KR) 10-2004-0038105

(51) Int. Cl. H01L 21/26

(52) U.S. Cl. 438/513

(57) ABSTRACT

There is provided a method for producing a solid element plasma from a solid lump and a plasma source used in the method. The method of the present invention comprises colliding a solid lump with accelerated particles or lasers to detach solid atoms from the solid lump within a first chamber inside which sputtering of solid atoms is performed, directing the solid atoms to a second chamber inside which plasma discharge is performed, applying a voltage to the second chamber to produce a plasma of solid atoms through plasma discharge, and contacting the plasma of solid atoms to a target to be treated. The present invention avoids problems caused from impurities and poisonous gases of conventional systems adopting a solid element-containing gas as a source of solid element.

### TECHNICAL FIELD

The present invention relates to a method for producing a solid element plasma. The present invention also relates to a plasma source, more specifically, to a solid element plasma source. The solid element plasma can be used as a remote plasma source, or in a surface modification such as thin film deposition and ion implantation.

### BACKGROUND ART

One exemplary embodiment of conventional methods widely used in thin film growth of solid element, such as silicon deposition, carbon nano-tube growth and ion implanting, comprises heating a target to a very high temperature, and contacting a solid element-containing gas to the target such that the solid element-containing gas undergoes a pyrolysis and solid atoms produced are deposited onto the target. However, this method requires heating of the target to the very high temperature, and its application is highly limited.

Another exemplary embodiment of the conventional methods widely used in thin film growth is to use plasma of a solid element-containing gas. Specifically, a high voltage is applied to the solid element-containing gas to produce a plasma and the plasma produced collides with a target to accomplish thin film deposition. However, the method suffers from disadvantages that highly pure thin film growth is unattainable, due to impurities produced from additional components contained in the gas other than the solid element. In order to accomplish high purity, very high temperature is required to the target.

For instance, in order to accomplish carbon nano-tube growth, methane (CH₄) is used as a carbon source. However, four hydrogen elements present in the methane gas act as an impurity. For silicon deposition, silane (SiH₄) containing a silicon element is used. However, the silane is a highly toxic gas, and four hydrogen elements present in the silane gas produce impurities. Likewise, PH₃, AsH₃, and BF₃ are used in ion implantation. These gases are very strong poisonous gases, so very strict equipment standard is required. Further, additional processes, such as high temperature heating, are required during implantation, to eliminate adverse effects caused from impurities (hydrogen elements, fluorine elements).

### DISCLOSURE OF INVENTION

Technical Problem

To solve the above mentioned problems caused by use of a solid element-containing gas, such as generation of impurities and harmfulness of poisonous gases, an object of the present invention is to provide a method for producing a solid element plasma through direct sputtering of solid atoms from a solid lump followed by plasma generation of the solid atoms.

Another object of the present invention is to provide a solid element plasma source used in the method.

Technical Solution

The above objects and others which will be described in the detailed description of the specification can be accomplished by provision of a method for producing a solid element plasma, comprising colliding a solid lump with accelerated particles or lasers to detach solid atoms from the solid lump within a first chamber inside which sputtering of solid atoms is performed, directing the solid atoms to a second chamber inside which plasma discharge is performed, applying a voltage to the second chamber to produce a plasma of solid atoms through plasma discharge, and contacting the plasma of solid atoms to a target to be treated.

According to another preferred embodiment of the present invention, there is provided a solid element plasma source comprising a first chamber inside which sputtering of solid atoms is performed by collision of a solid lump with accelerated particles or lasers followed by detachment of solid atoms from the solid lump, a second chamber inside which plasma discharge is performed by application of a voltage that initiates plasma discharge of the sputtered solid atoms, and a transporting member which provides a passage of the sputtered solid atoms from the first chamber to the second chamber.

Advantageous Effects

The plasma formation method and the solid element plasma source according to the present invention solve the problems caused from use of solid element-containing gases. All the solid elements-containing gases contain impurities such as hydrogen or fluorine. Therefore, contamination by hydrogen or fluorine is necessarily accompanied. The present invention uses solid atoms sputtered from a solid lump thereof such that contamination by hydrogen or fluorine does not take place. Further, the present invention does not require pyrolysis of gases such that thin film deposition can be achieved under low temperature. In addition, most of the solid elements-containing gases are too poisonous to be applied in a normal environment. However, the solid element plasma source according to the present invention does not use poisonous gases. Therefore, implanting may be achieved without any danger of poisonous gases and difficulties caused by impurities.

The plasma formation method and the solid element plasma source according to the present invention is distinguished from conventional sputters in that both the solid lump and the target are not in the same chamber but rather, the solid lump is located in the first chamber inside which sputtering is performed, and the target is separately located in the second chamber, which is connected to the first chamber through the transporting member and inside which plasma discharge is performed. Further, while the conventional sputters directly use the sputtered atoms without any conversion into plasma, the method and the apparatus according to the present invention convert the sputtered atoms into the plasma.

### BRIEF DESCRIPTION OF THE DRAWINGS

FIG. 1 is a drawing showing a preferred embodiment of the solid element plasma source, in accordance with the present invention.

FIG. 2 is a horizontal, cross-sectional view showing another preferred embodiment of the solid element plasma source, in accordance with the present invention.

FIG. 3 is a perpendicular, cross-sectional view showing a specific embodiment of the solid element plasma source, in accordance with the present invention.

### MODE FOR THE INVENTION

The present invention relates to a method for producing a solid element plasma, more specifically, a method of producing a solid element plasma from a solid lump. The method comprises colliding a solid lump with accelerated particles or lasers to detach solid atoms from the solid lump within a first chamber inside which sputtering of solid atoms is performed, directing the solid atoms to a second chamber inside which plasma discharge is performed, applying a voltage to the second chamber to produce a plasma of solid atoms through plasma discharge, and contacting the plasma of solid atoms to a target to be treated.

A first special feature of the present invention is to use a solid lump of solid element to obtain a solid element plasma. In the prior art, solid element-containing gases were used to produce a solid element plasma. However, the prior art was suffered from impurities and toxicity of the gases. For example, in the prior art, methane (CH₄) was used as a source of a carbon atom, silane (SiH₄) as a source of a silicon atom, boron trifluoride (BF₃) as a source of a boron atom, phosphine (PH₃) as a source of a phosphor atom and arsine (AsH₃) as a source of an arsenic atom, respectively. When the gases are used, however, other atoms (hydrogen or fluoride) composing the gases act as impurities. Furthermore, silane (SiH₄), boron trifluoride (BF₃) and phosphine (PH₃) are highly toxic material and any danger of gas leakage needs to be completely removed. But, the present invention avoids such problems, by using a solid lump as a source of a solid element plasma. For instance, in carbon nano-tube growth, a lump of solid carbon is located in a first chamber inside which sputtering is performed. Accelerated particles or lasers are collided with the solid lump. With aid of energy exchange from accelerated particles or lasers, solid atoms are sputtered from the solid lump. And then, the solid atoms are subjected to plasma discharge in the following step. The method eliminates adverse effects caused by other components contained in a gas other than carbon atom. Therefore, heating of a target to remove impurities is not required. Moreover, as a consequence, damages to the target, which may be caused by thermal expansion, could be reduced. Since no poisonous gas is used, the working environment could be improved.

Accelerated particles or lasers are used as a source for sputtering solid atoms from a solid lump. When accelerated particles are used, solid atoms are released through momentum exchange. Sputtering, such as magnetron sputtering, diode sputtering and RF sputtering can be adopted. Inert gases, such as helium, neon and argon, may be used to obtain accelerated particles. Sputtering with lasers may be also performed. This eliminates adverse effects caused by entrance of the inert gases into a plasma discharge space.

Solid atoms, which are sputtered from solid lumps, diffuse and move from the first chamber inside which sputtering has been performed, to the second chamber inside which plasma discharge is performed. Moving distance can be properly chosen, regarding a sputtering technique, energy of the accelerated particles, a kind of the solid atoms and purity of the solid lump.

Solid atoms, entered into the second chamber inside which plasma discharge is performed, undergoes plasma discharge by application of a high voltage. To obtain the plasma of solid atoms, a capacitatively coupled plasma discharge, an inductively coupled plasma discharge, a helicon discharge using plasma wave and a microwave plasma discharge may be applied. Among them, the inductively coupled plasma discharge that produces high density plasma at a low operating pressure is preferable. With regard to antenna shapes that are applicable to the inductively coupled plasma discharge, please refer to Korean Patent application Nos. 7010807/2000, 14578/1998, 35702/1999 and 43856/2001.

The plasma of solid atoms produced can be used in thin film growth, thin film deposition and ion implantation through collision to the target. As needed, produced plasma of solid atoms may be used as a remote plasma by directing them to outside of the second chamber.

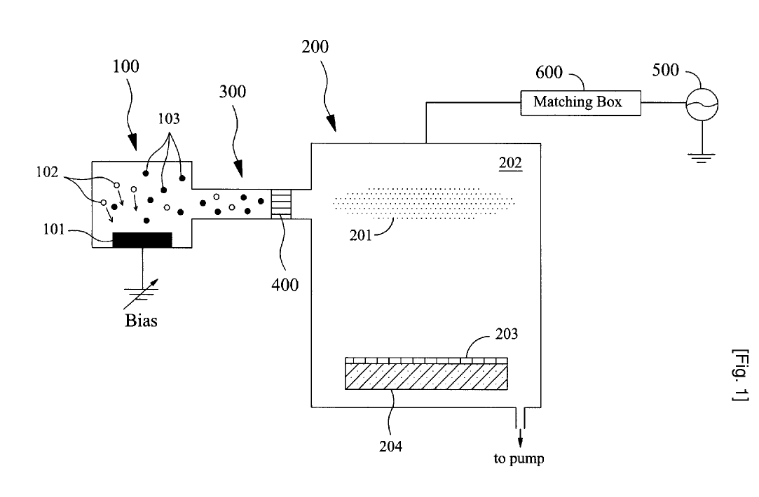

FIG. 1 is a drawing showing a preferred embodiment of a solid element plasma source used in the method. The solid element plasma source comprises a first chamber 100 inside which sputtering of solid atoms is performed by collision of a solid lump 101 with accelerated particles 102 followed by detachment of solid atoms 103 from the solid lump 101, a second chamber 200 inside which plasma discharge is performed by application of a voltage that initiates plasma discharge of the sputtered solid atoms, and a transporting member 300 which provides a passage of the sputtered solid atoms 103 from the first chamber 100 to the second chamber 200.

The solid lump of solid atoms 101 is located in the firstchamber 100, and there, sputtering is performed. The accelerated particles 102 of inert gases are collided with the solid lump 101 by impressing minus bias. Solid atoms 103 are released from the solid lump 101 through momentum exchange. Although FIG. 1 shows sputtering by the accelerated particles, sputtering for solid atoms may be performed by applying lasers. As mentioned above, sputtering by lasers can eliminate adverse effects caused by entrance of the inert gases into a plasma discharge space 202.

The solid atoms 103, which are produced by sputtering, leave the first chamber 100 by diffusion and move through the transporting member 300, which connects the first chamber 100 and the second chamber 200, to the second chamber 200 inside which plasma discharge is performed. The length of the transporting member 300 could be properly chosen regarding a sputtering technique, energy of the accelerated particles, kinds of the solid atoms and purity of the solid lump. Herein, a plasma limiter 400 can be additionally installed at a side of the transporting member 300. The plasma limiter 400 prohibits entrance of cations(for example, cationic argon), which may be produced inside the first chamber 100, into the plasma discharge space 202 of the second chamber 200, in order to eliminate adverse effects caused by the cations. To limit the cationic plasma, bias voltage may be used.

To the second chamber 200, an electric power supply 500 is connected and the plasma discharge is performed by the energy from the electric power supply 500. An impedance matching box 600 may be employed to apply a high voltage. Herein, the forms of discharges are not particularly limited. The plasma of solid atoms can be obtained through a capacitatively coupled plasma discharge, an inductively coupled plasma discharge, a helicon discharge using plasma wave, and a microwave plasma discharge. The inductively coupled plasma discharge is more preferable. The plasma 201 of solid atoms produced in the second chamber 200, is directed onto a target 203 positioned on a target holder 204 to treat the target 203.

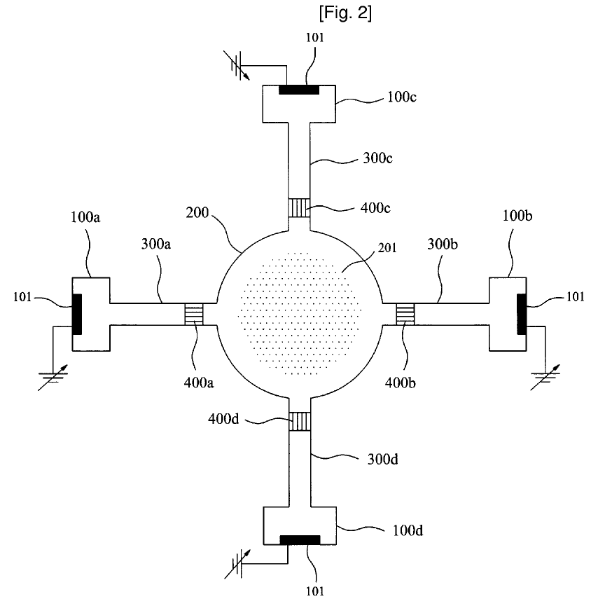

Meanwhile, the first chamber 100 can be employed in a multiple number depending on a required inner pressure of the second chamber 200. FIG. 2 is a horizontal, cross-sectional view showing another preferred embodiment of the solid element plasma source, in accordance with the present invention. Four first chambers 100a, 100b, 100c and 100d are connected to the second chamber 200 through the transporting members 300a, 300b, 300c and 300d. As shown in FIG. 2, it is desirable for the first chambers 100a, 100b, 100b, and 100d inside which the solid atoms are sputtered to be symmetrical located around the second chamber 200, to produce uniform plasma 201 of the solid atoms inside the second chamber 200.

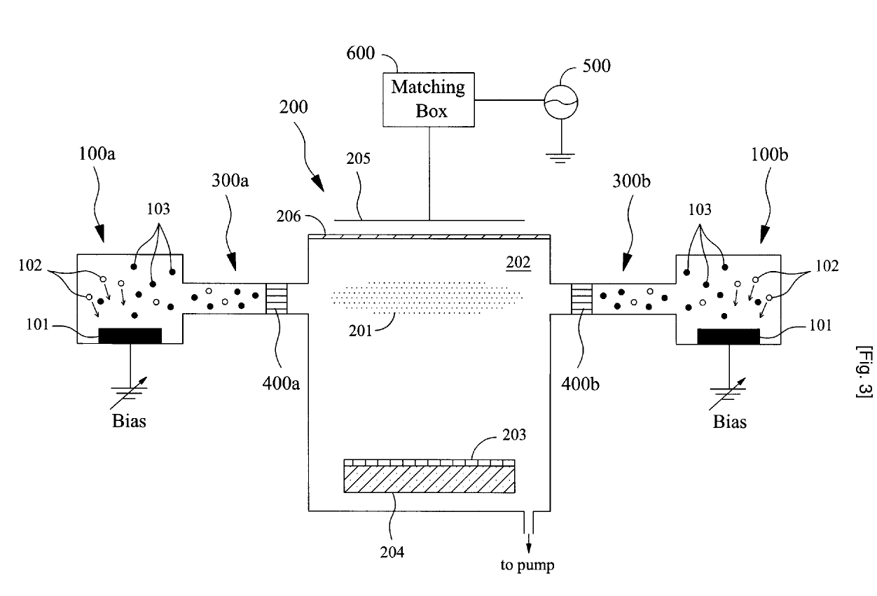

FIG. 3 is a perpendicular, cross-sectional view showing a specific embodiment of the solid element plasma source, in accordance with the present invention. A solid lump 101 of carbon is used and a negative bias voltage is applied onto the carbon solid lump 101. Argon 102 is used as an inert gas, and carbon atoms 103 are sputtered through magnetron sputtering. Four first chambers are employed as shown in FIG. 2, but only two first chambers 100a and 100b (totally, “100”) are presented in FIG. 3. Carbon atoms 103 generated in the first chambers 100 is introduced into a second chamber 200 inside which plasma discharge is performed, through transporting members 300a and 300b (totally, “300”),which connect the first chambers 100 to the second chamber 200. Plasma limiters 400a and 400b are installed at each side of the transporting members 300 to eliminate adverse effects caused by argon ions and ions of the solid atoms. An antenna 205 connected to an electric power supply 500, a plasma discharging space 202, a target 203 and a target holder 204 are installed in the second chamber 200.

The solid atoms 103, entered from the first chambers 100 into the plasma discharging space 202 of the second chamber 200 through the transportation pipes 300, undergo plasma discharge with aid of high voltage applied from the power supply 500 to the antenna 205. The plasma 201 of the solid atoms is directed to the target 203 and deposited to form a carbon thin film onto the target 203. As needed, the plasma may be outwardly directed and used as a remote plasma. The unexplained reference numerals 206 and 600 are a dielectric window and an impedance matching box, respectively.

In the FIGS. 1 to 3, the transporting member was used in a form of a transporting pipe. But the transporting member may be a grille.

As described, it should be evident that the present invention can be implemented through a variety of configurations in the aforementioned technical field without affecting, influencing or changing its spirit and scope of the invention. Therefore, it is to be understood that the examples and applications illustrated herein is intended to be in the nature of description rather than of limitation. Furthermore, the meaning, scope and higher conceptual understandings of the present patent application as well as modifications and variations that arise from thereof should be understood to be extensions to this current application.

1. A method for producing a solid element plasma, comprising colliding a solid lump with accelerated particles or lasers to detach solid atoms from the solid lump within a first chamber inside which sputtering of solid atoms is performed, directing the solid atoms to a second chamber inside which plasma discharge is performed, applying a voltage to the second chamber to produce a plasma of solid atoms through plasma discharge, and contacting the plasma of solid atoms to a target to be treated.

2. The method as set forth in claim 1, wherein the accelerated particles are formed of an inert gas.

3. The method as set forth in claim 1, wherein the plasma of solid atoms is used as a remote plasma, or applied to thin film growth, thin film deposition or ion implantation.

4. A solid element plasma source comprising a first chamber inside which sputtering of solid atoms is performed by collision of a solid lump with accelerated particles or lasers followed by detachment of solid atoms from the solid lump, a second chamber inside which plasma discharge is performed by application of a voltage that initiates plasma discharge of the sputtered solid atoms, and a transporting member which provides a passage of the sputtered solid atoms from the first chamber to the second chamber.

5. The solid element plasma source as set forth in claim 4, further comprising a plasma limiter installed at a side of the transporting member.

6. The solid element plasma source as set forth in claim 4, wherein the fist chamber is used in a multiple number and is connected to the second chamber through each independent transporting member.

7. The solid element plasma source as set forth in claim 4, wherein the solid lump is a lump of solid element selected from the group consisting of carbon, silicon, boron, phosphorus and arsenic.

8. The solid element plasma source as set forth in claim 4, wherein the transporting member is a transporting pipe or a grille.

9. A solid element plasma source, comprising:
a first chamber inside which sputtering of solid atoms is performed by collision of a solid lump with accelerated particles or lasers followed by detachment of solid atoms from the solid lump, wherein the solid lump is a lump of solid element selected from the group consisting of carbon, silicon, boron, phosphorus and arsenic;
a second chamber inside which plasma discharge is performed by application of a voltage that initiates plasma discharge of the sputtered solid atoms, wherein the second chamber comprises an antenna connected to an electric power supply, a plasma discharging space, a target and a target holder, and the solid atoms produced in the first chamber is converted into a plasma of solid atoms with aid of the voltage applied to the antenna; and
a transporting member which provides a passage of the sputtered solid atoms from the first chamber to the second chamber.
